(19) United States
(12) Patent Application Publication
(10) Pub. No.: US 2021/0227719 A1
(43) Pub. Date: Jul. 22, 2021

(54) HEAT COOLER

(71) Applicant: SHENZHEN ACCOMTECH COMMUNICATION ELECTRONICS CO., LTD., Shenzhen, Guandong (CN)

(72) Inventors: Tienan GUO, Shenzhen, (CN); Tielong GUO, Shenzhen (CN); Guanglin XU, Shenzhen (CN); Yonggang TAN, Shenzhen (CN)

(73) Assignee: Shenzhen Accomtech Communication Electronics Co., Ltd., Shenzhen, Guandong (CN)

(21) Appl. No.: 16/632,821

(22) PCT Filed: Apr. 19, 2019
(86) PCT No.: PCT/CN2019/083472

§ 371 Date: Jan. 21, 2020

(30) Foreign Application Priority Data
Aug. 17, 2018 (CN) 201810943401.9

(51) Int. Cl. H05K 7/20

(52) U.S. Cl. CPC H05K 7/20336; H05K 7/20318

(57) ABSTRACT

The present invention discloses a heat cooler including a lower member and an upper member attached to each other and a vacuum cavity interposed between the lower member and the upper member, wherein the working oil is filled within the vacuum cavity, and the working oil is phase-change circulated within the vacuum cavity according to an external temperature. The present invention implements minimization of an occupied space and implements a light and small device according to a simple constitution, thereby guaranteeing maximization of productivity and heat dissipation.

### TECHNICAL FIELD

The present invention relates to a heat cooler, in more detail, the cooler is configured with a vacuum cavity between a lower member and an upper member attached to each other, such that not only a capillary line is easily formed, but also as a lower member, the material within an electronic device may be directly used, and the heat cooler is not used as an additionally added part, but as a component part integrated with the electronic device, minimization of an occupied space can be implemented, and a light and small device may be implemented according to a simple constitution, thereby guaranteeing maximization of productivity and heat dissipation.

### BACKGROUND ART

Generally, a heat pipe is an electronic part that transmits heat from a heat portion to a heat dissipation portion through evaporation and condensation of a medium (e.g., working oil) to be able to dissipate heat within the electronic device.

Specifically speaking, after the heat pipe is implanted with a working oil, such as alcohol, ethanol and the like, into an internal portion of reduced pressure (vacuum state) thereof, if one side is heated, a liquid becomes vapor and flows to another side (in the vacuum state, the temperature required by the phase transition is comparatively low, that is, a characteristic that the phase change temperature from liquid to gas is low), on the other side, after the vapor becomes liquid through heat dissipation, the liquid restores to the structure of one side by means of capillary phenomenon.

FIG. 1a is a diagram illustrating a portable device including a heat pipe 120 in a prior art document (Patent No. 2015-0091873 published in Korea).

Referring to FIG. 1a, a portable device 100 includes: a circuit substrate 110 which includes at least one electronic part 110a; the heat pipe 120 which is configured on the electronic member 110a to dissipate heat occurring from the electronic part 110a; and a heat dissipation material which makes the circuit substrate 110 and the heat pipe 120 be adhered to each other.

The electronic part 110a may be an application processor (AP), a central processing unit (CPU) and a power management IC (PMIC). Such an electronic part 110a is a main heat source where heat occurs in the portable device. Thus, the heat pipe 120 should be configured on the electronic part 110a and may dissipate heat occurring in the electronic part 110a elsewhere.

FIG. 1b is a diagram illustrating an example of configuring a heat pipe on a circuit substrate in the prior art document.

The heat pipe 120 includes: an evaporator 310 which is configured on the electronic part 110a and absorbs heat occurring from the circuit substrate 110; a connection portion 320 which is formed in a side surface region of the circuit substrate 110 and transfers the absorbed heat toward a direction opposite to the electronic part 110a; and a condenser 330 which releases the transferred heat.

The evaporator 310 absorbs heat occurring in the electronic part 110a to change working oil into gas. The working oil which becomes gas moves to the condenser 330 along the connection portion 320. The condenser 330 releases the absorbed heat while condensing working oil which becomes gas into liquid. The condensed working oil moves to the evaporator 310 along the connection portion 320 again.

Thus, the heat pipe 120 may dissipate heat occurring in the circuit substrate 110 into the portable device outside the circuit substrate 110.

FIG. 1c is a diagram illustrating a heat pipe in the prior art document.

Referring to FIG. 1c, the portable device is a cross-sectional view in which the portable device in FIG. 1b is cut apart along line “X2”. The portion cut along line “X2” is the portion forming the connection portion 320 of the heat pipe 120. The heat pipe 120 may be constituted by a vapor cavity 410, a drainage wick 420 and a heat member 430.

Referring to FIG. 1c, the vapor cavity 410 may make a phase change of the heat absorbed from the circuit substrate 450 and become gas. The heat which becomes gas moves along the vapor cavity 410 and is transferred to the condenser 330. The drainage wick 420 surrounds the vapor cavity 410 which may make a phase change of the heat released from the condenser 330 and become liquid. The heat which becomes liquid is re-transferred to the evaporator 310 along the drainage wick 420. The heat member 430 is formed to be surrounding the drainage wick 420. The heat member 430 may be composed of at least one of or an alloy of more than two of aluminum (Al), copper (Cu), silver (Ag), titanium (Ti), chromium (Cr), gold (Au), carbon (C), nickel (Ni), iron (Fe), platinum (Pt), graphite and boron nitride (BN).

However, if the heat pipe 120 is utilized to absorb heat of the electronic part 110a and dissipate heat at a battery, the thickness of the heat pipe 120 is too large. When considering the width of the portable device, the electronic part 110a being inserted into the heat pipe 120 in a state of being directly connected to the battery 130 not only needs other space but also is inconvenient. Further, performing press after placing the drainage wick 420 within the vapor cavity 410 usually causes an undesirable result. Moreover, the heat pipe 120 cannot freely curve or bend, and there is a problem for being difficult to be disposed within the electronic device.

FIG. 2 is a cross-sectional view illustrating a process of manufacturing a heat pipe P used in a general electronic device.

The heat pipe used in an electronic device is designed as: a mesh (M) is inserted into the pipe P composed of copper, and is flattened after a working oil R is added in a vacuum processing state, as shown in the prior art document, the heat pipe is configured next to the circuit substrate and performs heat dissipation according to a phase change of gasification and condensation of the working oil R.

However, such a conventional heat pipe for an electronic device has a problem that when a mesh (M) is inserted into the pipe P composed of copper, and is flattened after a working oil R is added in a vacuum processing state, a large number of undesirable results may occur.

### SUMMARY

In light of defects existing in the prior art, the present invention provides the following solution.

The present invention provides a heat cooler comprising:

a lower member and an upper member attached to each other;

a vacuum cavity which is configured between the lower member and the upper member and fulfills functions of a condenser, a moving portion and a gasification portion;

a capillary line which is configured within the vacuum cavity; and

a working oil which is filled within the vacuum cavity, the working oil moves along the moving portion after being gasified at the gasification portion due to a high temperature, the working oil returns back to the moving portion and the gasification portion along the capillary line again after being liquefied at the condenser due to a low temperature, and the heat cooler implements heat dissipation through a phase change of the working oil in the above circulation.

Alternatively, the vacuum cavity is configured on the lower member or configured on the lower member and the upper member.

Alternatively, the condenser is formed to be wider and deeper as compared with the moving portion and the gasification portion.

Alternatively, the capillary line is formed on a bottom surface of the vacuum cavity configured on the lower member.

Alternatively, the capillary line is formed at both sides of the vacuum cavity, and a channel is disposed between the capillary line.

Alternatively, the capillary line is formed at a center of the vacuum cavity, and channels are disposed at both sides of the capillary line, respectively.

Alternatively, the lower member and the upper member are planar areas, and the vacuum cavity is a linear pipeline within the planar area.

Alternatively, the vacuum cavity of the linear pipeline is a plurality of linear pipelines connecting to each other with the condenser as a center within the planar area.

Alternatively, the lower member comprises a placing groove along the periphery of the vacuum cavity, and the upper member is placed in and attached to the placing groove.

Alternatively, the lower member comprises a plurality of guiding bumps projecting along the periphery of the vacuum cavity, and the upper member comprises guiding holes fitting the guiding bumps.

Alternatively, the capillary line is a thin slice having a capillary, and is interposed between the lower member and the upper member and inserted into the vacuum cavity.

Alternatively, the lower member further comprises a plurality of heat dissipation pins for heat dissipation.

Through the above technical features, effects of the present invention lie in that: a vacuum cavity is configured between a lower member and an upper member attached to each other, such that not only a capillary line is easily formed, but also the material within an electronic device may be directly used as the lower member, the heat cooler is a component part integrated with the electronic device without being an additionally added part, minimization of an occupied space can be implemented, and a light and small device may be implemented according to a simple constitution, thereby guaranteeing maximization of productivity and heat dissipation.

Furthermore, the condenser of the present invention is formed to be wider and deeper as compared with the moving portion and the gasification portion, such that an effect of preventing a fluid dry phenomenon of the working oil while guaranteeing a high efficient circulation of the working oil can be achieved.

Furthermore, the present invention makes a capillary line be formed at a bottom surface of the vacuum cavity configured on the lower member, thereby achieving an effect of implementing maximization of a diffusion phenomenon of the working oil.

Furthermore, the present invention makes capillary lines be formed at both sides of the vacuum cavity and makes channels be formed between the capillary lines, such that an effect of rapidly circulating through the capillary lines and the central channel while the working oil is sufficient can be achieved.

Furthermore, the present invention makes a capillary line be formed at a center of the vacuum cavity and makes channels be disposed at both sides of the capillary line, respectively, such that an effect of rapidly circulating through the capillary line and the channels at both sides while the working oil is sufficient can be achieved.

Furthermore, the vacuum cavity of the linear pipeline of the present invention is a plurality of linear pipelines connecting to each other with the condenser as a center within the planar area, such that an effect of maximizing heat dissipation can be guaranteed.

Furthermore, the upper member of the present invention is placed within and attached to the placing groove of the lower member, and achieves an effect of facilitating firm fixing and minimizing a whole thickness.

Furthermore, the present invention achieves an effect of guaranteeing mutual simple assembly and firm assembly between the lower member and the upper member by means of the guiding bump and the guiding hole.

Furthermore, the capillary line of the present invention is a thin slice having a capillary which is configured and interposed between the lower member and the upper member, and achieves an effect of pre-forming a slimmer and various capillary lines on the thin slice while guaranteeing convenience of the assembly operation.

Furthermore, the lower member of the present invention further comprises a plurality of heat dissipation pins for heat dissipation, thereby achieving the effect of seeking maximization of heat dissipation.

### BRIEF DESCRIPTION OF THE DRAWINGS

FIG. 1a is a diagram illustrating a portable device including a heat pipe in a prior art document;

FIG. 1b is a diagram illustrating an example of configuring a heat pipe on a circuit substrate in the prior art document;

FIG. 1c is a diagram illustrating a heat pipe in the prior art document;

FIG. 2 is a cross-sectional view illustrating a process of manufacturing a general heat pipe for the use of an electronic device;

FIG. 3 is an exploded perspective view illustrating a heat cooler of the present invention;

FIGS. 4a and 4b are cross-sectional view illustrating a heat cooler of an embodiment of the present invention;

FIGS. 5a and 5b are cross-sectional view illustrating a capillary line applied in a heat cooler of an embodiment of the present invention, respectively;

FIGS. 6a and 6b are exploded perspective views illustrating a vacuum cavity applied in a heat cooler of an embodiment of the present invention, respectively;

FIGS. 7a to 7c are exploded perspective views illustrating a heat cooler of an embodiment of the present invention or cut exploded perspective views illustrating main portions of a heat cooler of an embodiment of the present invention;

FIG. 8a is a perspective view and an exploded perspective view illustrating a circuit substrate and a shield can within an electronic device to which a heat cooler of the present invention is applied;

FIG. 8b is a exploded perspective view illustrating a frame of a cellular phone to which a heat cooler is applied of the present invention; and

FIGS. 9a and 9b are exploded perspective views illustrating an LED lamp frame to which a heat cooler of the present invention is applied.

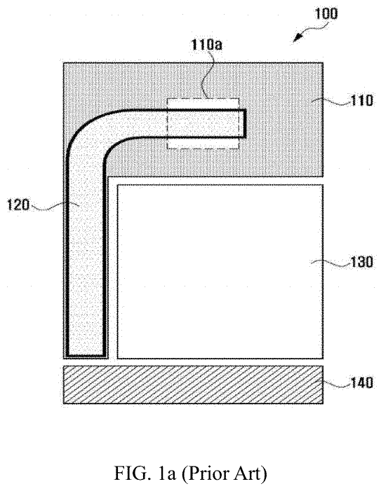

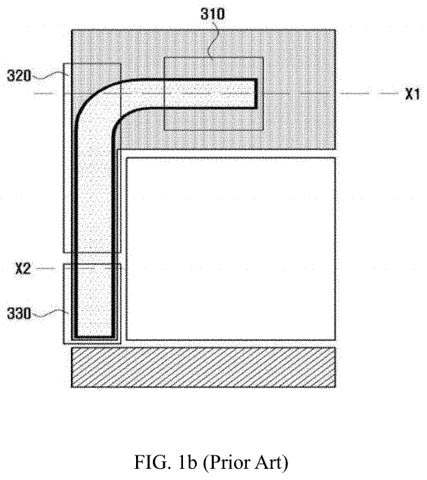

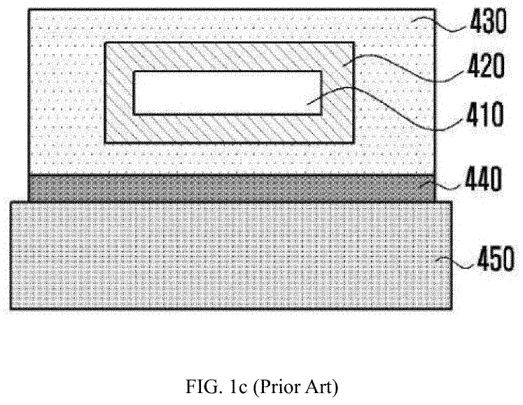

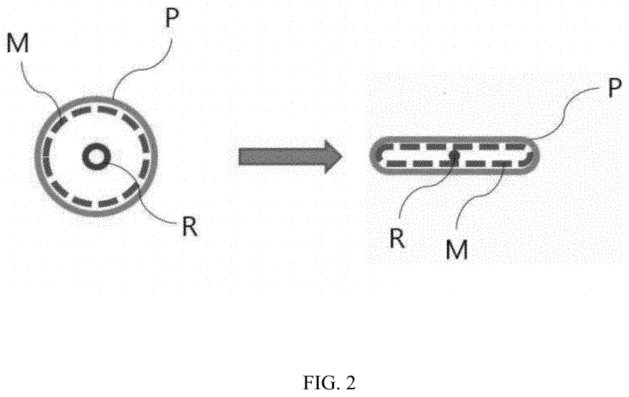

The Reference Signs of the Drawings are as Follows:

H: lower member

H1: Heat dissipation pin

H2: Placing groove

H3: Guiding bump

S: upper member

S1: Guiding hole

J: Adhering means

C: Vacuum cavity

C1: Condenser

C2: moving portion

C3: Gasification portion

M: Capillary line

M1: Thin slice

R: working oil

U: Channel

10: Shield can

100: Circuit substrate

200: Frame of cellular phone

300: LED lamp frame

### DETAILED DESCRIPTION

Referring to the drawings, preferred embodiments of the heat cooler of the present invention are illustrated, the embodiments thereof may be multiple, and purposes, characteristics and advantages of the present invention may be better understood through these embodiments.

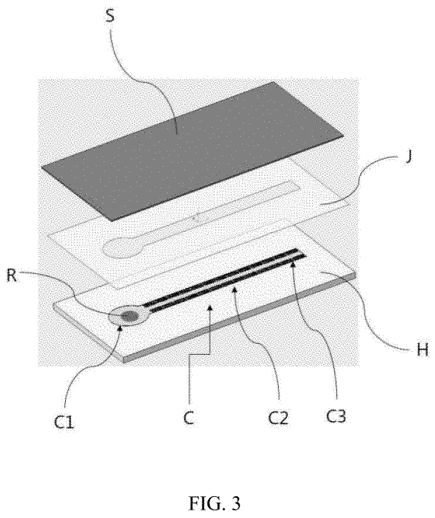

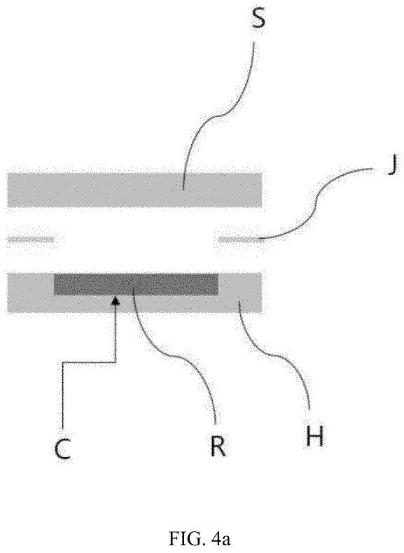

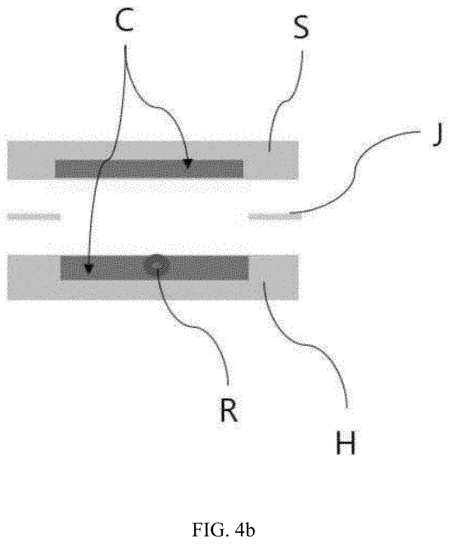

FIG. 3 is a exploded perspective view illustrating a heat cooler of the present invention. FIGS. 4a and 4b are cross-sectional view illustrating a heat cooler of an embodiment of the present invention.

The heat cooler of the present invention includes, as illustrated in FIGS. 3 to 4b: a lower member H and an upper member S attached to each other; a vacuum cavity C which is configured between the lower member H and the upper member S and fulfills functions of a condenser C1, a moving portion C2 and a gasification portion C3; a capillary line M which is configured within the vacuum cavity C; and a working oil R which is filled within the vacuum cavity C, wherein the working oil R moves along a moving portion C2 after being gasified at the gasification portion C3 due to a high temperature, the working oil R returns back to the moving portion C2 and the gasification portion C3 along the capillary line M again after being liquefied at the condenser C1 due to a low temperature, and the cooler implements heat dissipation through a phase change of the working oil R in the above circulation.

The working oil R within the vacuum cavity C passes through the moving portion C2 and is liquefied at the condenser C1 in a low heat state after being gasified according to high heat occurring in various parts, such as a circuit substrate 100, an IC chip, a CPU, an LED and the like, within an electronic device, such as a cellular phone or a tablet computer, a household appliance or an LED lamp and the like being in contact with or approaching the gasification portion C3 (the vacuum cavity C is in a vacuum state, and thus, the gasification temperature of the working oil R becomes lower, that is, the gasification is started from about 30˜50° C., the heat dissipation temperature is lowered to actively implement heat dissipation within the electronic device). The present invention implements heat dissipation through the above phase change process such that heat within the electronic device can be actively cooled, and continuous heat dissipation through a repeated gasification and condensation circulation of the working oil R starting from the gasification portion C3 and arriving at the moving portion C2 and the condenser C1 along the capillary line M can be implemented.

Especially, a vacuum cavity C is configured between the lower member H and the upper member S attached to each other, such that not only the capillary line M is easily formed, but also the material (the material constituted of a metal, a FCCL (Flexible Copper Clad Laminate), a cooling plastic and the like) within the electronic device may be directly used as the lower member H, such that the heat cooler is not used as a component part integrated with the electronic device without being an additionally added part, minimization of an occupied space can be implemented, and a light and small device may be implemented according to a simple constitution, thereby guaranteeing maximization of productivity and heat dissipation.

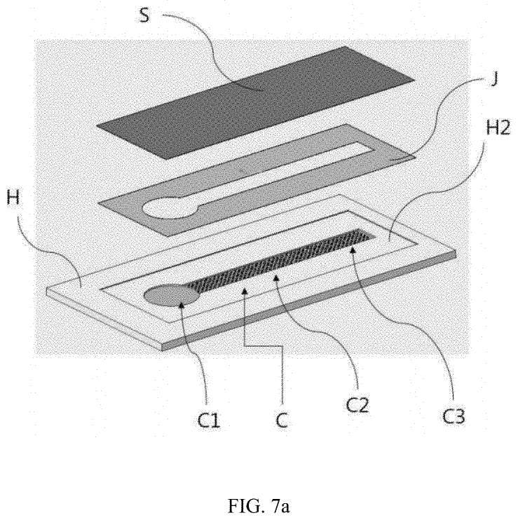

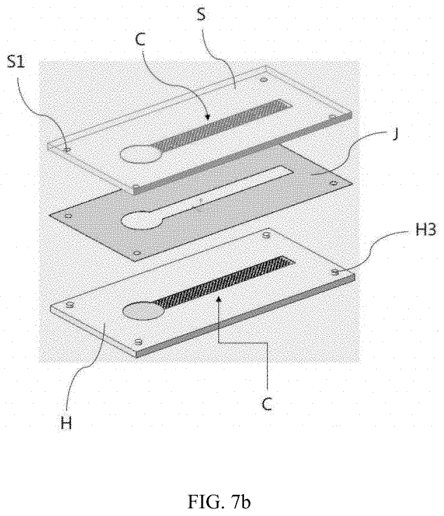

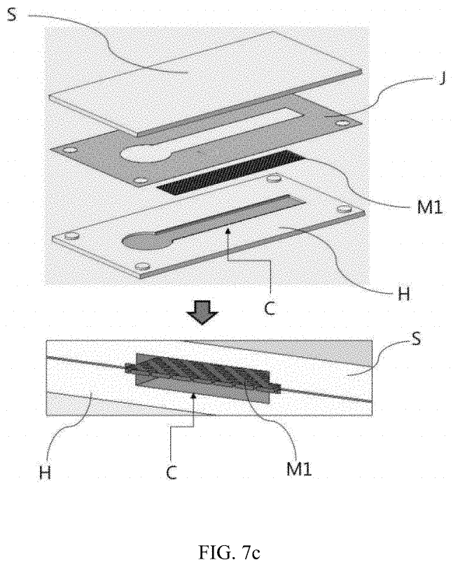

According to the present invention, the vacuum cavity C may be, as shown in FIG. 4a, configured on the lower member H to accomplish attaching using a simple adhering means J (an adhesive or a double sided tape, and the like) of the upper member S, and may be certainly, as shown in FIG. 4b and the subsequent FIG. 7b, configured on the lower member H and the upper member S to accomplish attaching through mutual adhesion.

On the other hand, the condenser C1 of the vacuum cavity C applied in the heat cooler of the present invention is, as shown in FIG. 3, formed to be comparatively wider and deeper than the moving portion C2 and the gasification portion C3, and the fluid dry phenomenon of the working oil R is further prevented while high efficient circulation of the working oil R is ensured.

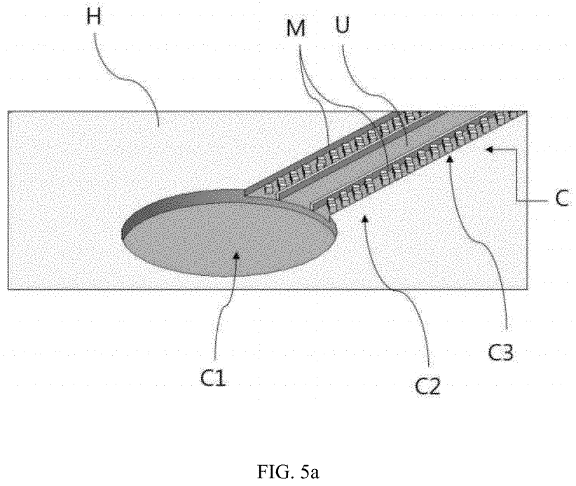

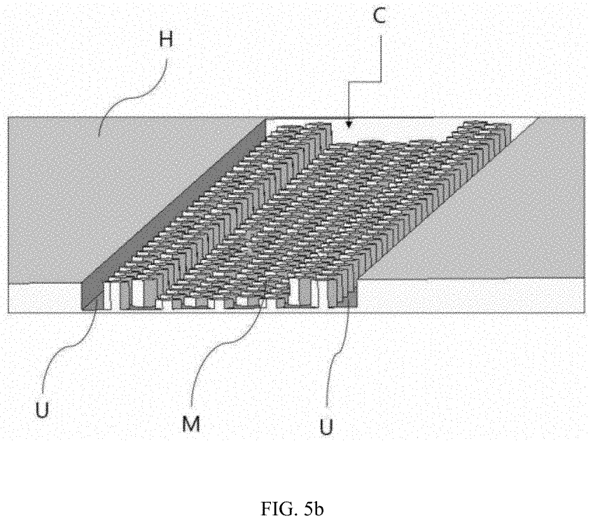

FIGS. 5a and 5b are cross-sectional views illustrating a capillary line M applied in a heat cooler of an embodiment of the present invention, respectively.

The working oil R is liquefied at the condenser C1 after being gasified at the gasification portion C3, so that the working oil R may diffuse again along the capillary line M and backflow to the gasification portion C3. In the present invention, the capillary line M is formed at a bottom surface of the vacuum cavity C configured on the lower member H, so that diffusion phenomenon of the working oil R is implemented to be maximized.

As shown in FIG. 5a, the capillary lines M are formed at both sides of the vacuum cavity C, and a channel U is disposed between the capillary lines M. When the working oil R is sufficient, it may be rapidly circulated through the capillary lines M and the channel U therebetween.

As shown in FIG. 5b, the capillary line M is formed at a center of the vacuum cavity C, and channels U are disposed at both sides of the capillary line M, respectively. When the working oil R is sufficient, it may be rapidly circulated through the capillary line M and the channels U at both sides.

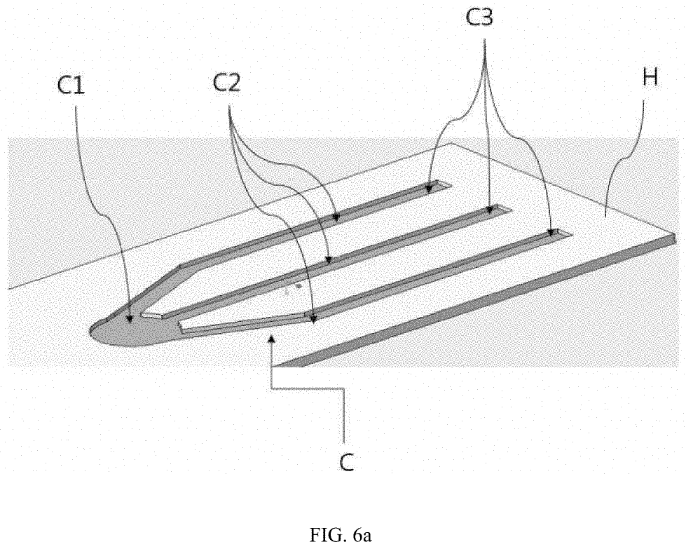

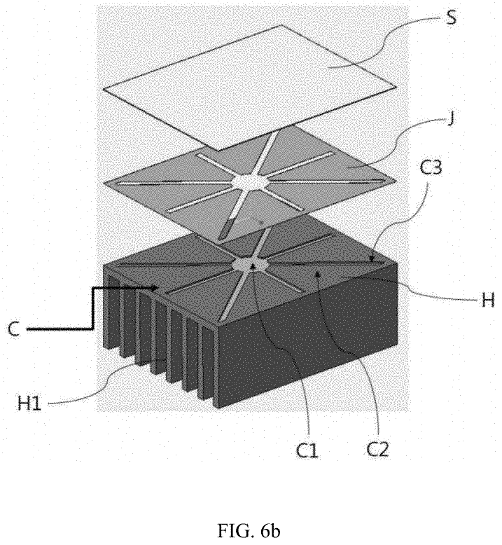

FIGS. 6a and 6b are exploded perspective views illustrating a vacuum cavity C applied in a heat cooler of an embodiment of the present invention, respectively.

According to the present invention, the lower member H and the upper member S are composed of planar areas, and the vacuum cavity C is formed in a manner of linear pipeline within the planar area, such that the circulation of the working oil R can be guaranteed. Furthermore, as shown in FIGS. 6a and 6b, the vacuum cavity in a manner of linear pipeline is a plurality of linear pipelines connecting to each other with the condenser as a center within the planar area, such that maximization of heat dissipation can be guaranteed.

FIGS. 7a to 7c are exploded perspective views illustrating a heat cooler of an embodiment of the present invention or cut perspective views illustrating main portions of a heat cooler of an embodiment of the present invention.

According to the embodiment of the present invention, as shown in FIG. 7a, the lower member H includes a placing groove H2 configured along the periphery of the vacuum cavity C, and the upper member S is placed within and attached to the placing groove H2. That is, the upper member S is placed within and attached to the placing groove H2 of the lower member H, such that the upper member S is firmly fixed and minimization of the whole thickness can be implemented.

As shown in FIG. 7b, the lower member H includes guiding bumps H3 disposed convexly along the periphery of the vacuum cavity C, and the upper member S includes guiding holes S1 fitting the guiding bumps H3, thereby guaranteeing mutual simple and firm assembly between the lower member H and the upper member S.

As shown in FIG. 7c, the capillary line M is a thin slice M1 having a capillary, and the capillary line M is interposed between the lower member H and the upper member S so as to be simply inserted into the vacuum cavity C. As a result, slimmer and various capillary lines M may be pre-formed on the thin slice M1 while guaranteeing convenience of the assembly operation.

On the other hand, according to the embodiment of the present invention, the lower member H, as shown in FIG. 6b, further includes a plurality of heat dissipation pins H1 for heat dissipation to facilitate maximization of heat dissipation.

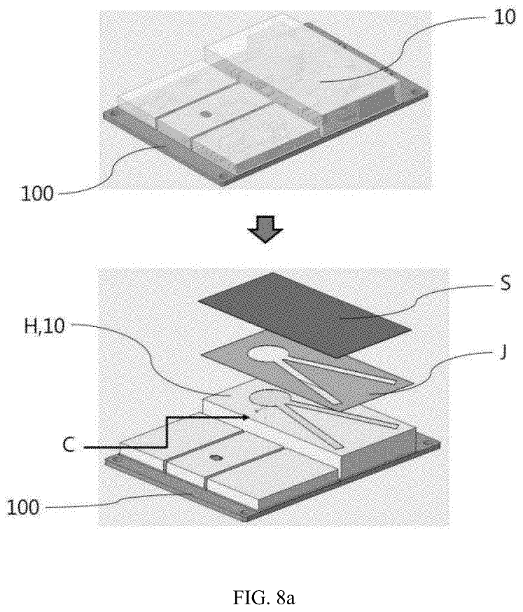

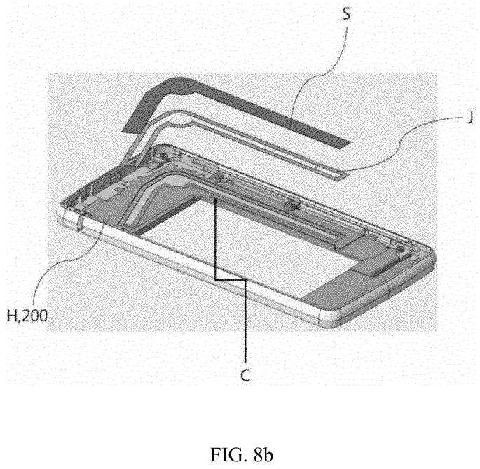

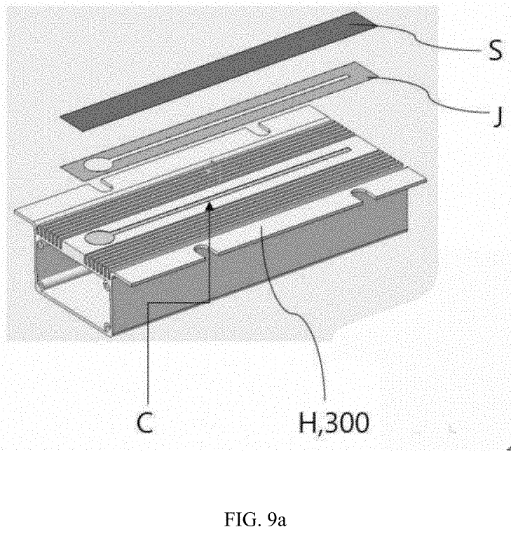

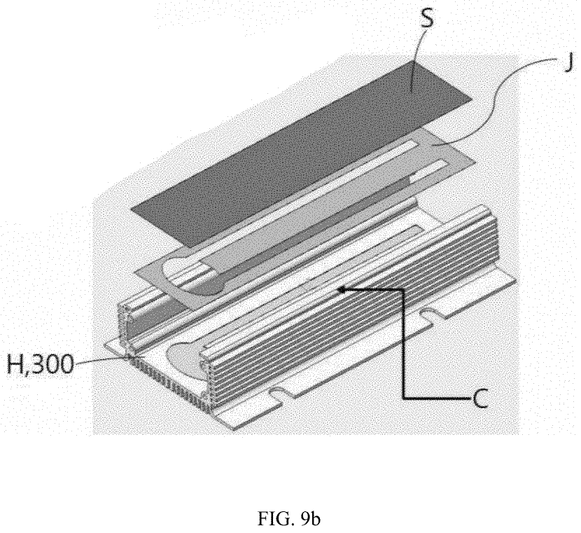

FIG. 8a is a perspective view and an exploded perspective view illustrating a circuit substrate 110 and a shield can within an electronic device to which a heat cooler of the present invention is applied. FIG. 8b is an exploded perspective view illustrating a frame 200 of a cellular phone to which a heat cooler of the present invention is applied. FIGS. 9a and 9b are exploded perspective views illustrating an LED lamp frame 300 to which a heat cooler of the present invention is applied.

The present invention consists of the lower member H and the upper member S as a basic constitution. As shown in FIG. 8a, a shield can 10 for protecting various circuit parts, such as a cellular phone and the like, after they are loaded may be used as a lower member H to finish the heat cooler. As shown in FIG. 8b, a frame 200 of a cellular phone may be used as a lower member H to finish the heat cooler. As shown in FIGS. 9a and 9b, an LED lamp frame 300 may be used as a lower member H to finish the heat cooler.

What is claimed is:

1. A heat cooler comprising:
a lower member and an upper member attached to each other;
a vacuum cavity which is configured between the lower member and the upper member and fulfills functions of a condenser, a moving portion and a gasification portion;
a capillary line which is configured within the vacuum cavity; and
a working oil which is filled within the vacuum cavity, the working oil moves along the moving portion after being gasified at the gasification portion due to a high temperature, the working oil returns back to the moving portion and the gasification portion along the capillary line again after being liquefied at the condenser due to a low temperature, and the heat cooler implements heat dissipation through a phase change of the working oil in the above circulation.

2. The heat cooler of claim 1, wherein the vacuum cavity is configured on the lower member or configured on the lower member and the upper member.

3. The heat cooler of claim 2, wherein the condenser is formed to be wider and deeper as compared with the moving portion and the gasification portion.

4. The heat cooler of claim 2, wherein the capillary line is formed on a bottom surface of the vacuum cavity configured on the lower member.

5. The heat cooler of claim 4, wherein the capillary line is formed at both sides of the vacuum cavity, and a channel is disposed between the capillary line.

6. The heat cooler of claim 4, wherein the capillary line is formed at a center of the vacuum cavity, and channels are disposed at both sides of the capillary line, respectively.

7. The heat cooler of claim 1, wherein the lower member and the upper member are planar areas, and the vacuum cavity is a linear pipeline within the planar area.

8. The heat cooler of claim 7, wherein the vacuum cavity of the linear pipeline is a plurality of linear pipelines connecting to each other with the condenser as a center within the planar area.

9. The heat cooler of claim 2, wherein the lower member comprises a placing groove along the periphery of the vacuum cavity, and the upper member is placed in and attached to the placing groove.

10. The heat cooler of claim 2, wherein the lower member comprises a plurality of guiding s bumps projecting along the periphery of the vacuum cavity, and the upper member comprises guiding holes fitting the guiding bumps.

11. The heat cooler of claim 1, wherein the capillary line is a thin slice having a capillary, and is interposed between the lower member and the upper member and inserted into the vacuum cavity.

12. The heat cooler of claim 1, wherein the lower member further comprises a plurality of heat dissipation pins for heat dissipation.
